(19) United States
(12) Patent Application Publication
(10) Pub. No.: US 2010/0326490 A1
(43) Pub. Date: Dec. 30, 2010

(54) PHOTOVOLTAIC PANEL WITH HOT PLUG CONNECTOR

(76) Inventors: Russell V. Tagliareni, Lafayette, NJ (US); Shihab Kuran, Green Brook, NJ (US)

Correspondence Address: LESTER H. BIRNBAUM, 6 OAKMOUNT COURT, SIMPSONVILLE, SC, 29681, US

(21) Appl. No.: 12/735,345

(22) PCT Filed: Jan. 6, 2009
(86) PCT No.: PCT/US09/00028

§ 371 Date: Aug. 27, 2010

Related U.S. Application Data
(60) Provisional application No. 61/010,463, filed on Jan. 9, 2008.

(51) Int. Cl. H01L 31/042; H05K 7/02

(52) U.S. Cl. 136/244; 361/807

(57) ABSTRACT

A photovoltaic assembly is provided, which includes a docking station to facilitate the transmission of DC electricity from the photovoltaic panel and the transmission of AC electricity to various electric appliances. The photovoltaic assembly includes an inverter module that connects to the docking station through a connector. The system enables replacement and insertion of the inverter module without affecting the functioning of the photovoltaic assembly.

### FIELD OF THE INVENTION

The invention disclosed here relates, in general, to the field of photovoltaic panels, and more specifically, to a hot plug connector for electrically connecting equipment, such as an inverter, to the photovoltaic panels. The invention also relates to means for connecting and disconnecting the output of equipments, such as an inverter, to load or other AC electric devices while such devices are electrically active.

### BACKGROUND

A photovoltaic panel is a combination of solar cells which converts sunlight into usable energy. An arrangement of more than one photovoltaic panel connected to provide a cumulative energy output is referred to as a photovoltaic array. The photovoltaic panel produces energy in the form of Direct Current (DC) electricity. DC electricity can be converted into Alternating Current (AC) electricity and used to operate various electric. devices, for example, household appliances. The conversion of DC electricity to AC electricity is carried out by using an inverter. For the purpose of description, an assembly of elements required to convert sunlight into usable electric power, for example AC electricity, is hereinafter referred to as a photovoltaic assembly. For example, the photovoltaic assembly includes a photovoltaic panel, inverter, wires and other elements, such as a battery. According to the current state of the art, the photovoltaic panel is connected to the inverter by means of conductors or wires.

In general, the lifetime of an inverter may be shorter than that of the photovoltaic panel. As a result, the inverter may have to be replaced during the life of the photovoltaic panel. If the inverter functions improperly or fails, a considerable amount of manual effort is required to replace it with a properly functioning inverter. Existing wire connections between the inverter input and the photovoltaic panel and between the inverter output and the load need to be disconnected. Further, new connections need to be established between the properly functioning inverter input and the photovoltaic panel, and between the inverter output and the load, while the system of several photovoltaic panels in the photovoltaic array is operational. Furthermore, aligning the connector of the properly functioning inverter to the connector of the photovoltaic panel and mechanically mounting the properly functioning inverter may also require a considerable amount of time and manual effort.

The process of replacing elements such as the inverter involves disengaging electric wires between the inverter and the photovoltaic panel along with disengaging electric wires between the inverter and loads or other electric devices using AC voltage from the inverter, while the output voltage is present on the branch circuit of a typical system. Further, the process also involves making new electric connections between the photovoltaic panel, a new inverter and the loads or electric devices using the AC voltage from the inverter. Since electrical wires are involved in this process, a skilled person is required to replace the elements. The manual effort required and the presence of a skilled person for fault repair increases the downtime and operational cost of power generation.

In light of the above, there is a need for a photovoltaic assembly with components, such as an inverter, which can be replaced easily by an unskilled person with minimum effort and time, while the system of several photovoltaic panels in the photovoltaic array is operational.

### BRIEF DESCRIPTION OF THE DRAWINGS

The preferred embodiments of the invention will hereinafter be described in conjunction with the appended drawings provided to illustrate and not to limit the invention, wherein like designations denote like elements, and in which:

FIGS. 1(a) and 1(b) are block diagrams of illustrating exemplary arrangements in which various embodiments of the present invention can be practiced;

FIG. 2 illustrates a perspective view of a photovoltaic assembly, in accordance with an embodiment of the present invention;

FIG. 3 illustrates a perspective view of a docking station, in accordance with an embodiment of the present invention;

FIG. 4 illustrates a perspective view of an inverter module, in accordance with an embodiment of the present invention;

FIG. 5 illustrates a perspective view of a docking station, in accordance with another embodiment of the present invention; and

FIG. 6 illustrates a perspective view of an inverter module, in accordance with another embodiment of the present invention.

FIG. 7 illustrates a planar view of a photovoltaic assembly, in accordance with an embodiment of the present invention;

FIG. 8 illustrates a perspective view of a photovoltaic assembly, in accordance with another embodiment of the present invention;

FIG. 9 illustrates a planar view of a photovoltaic assembly, in accordance with yet another embodiment of the present invention; and

FIG. 10 illustrates a planar view of a photovoltaic assembly, in accordance with still another embodiment of the present invention.

### DETAILED DESCRIPTION OF THE INVENTION

While the preferred embodiments of the invention have been illustrated and described, it will be clear that the invention is not limited to these embodiments only. Numerous modifications, changes, variations, substitutions and equivalents will be apparent to those skilled in the art without departing from the spirit and scope of the invention.

In an embodiment, the invention provides a photovoltaic assembly with a docking station and an inverter module. The docking station is either fixedly or removably mounted on a photovoltaic panel of the photovoltaic assembly. Further, the docking station has a first connector and the inverter module has a corresponding second connector. The first connector and the second connector enable the connection of the inverter to the docking station, and any other load the inverter may be connected to. The connectors are hot plug connectors, such that the inverter module can be disconnected from the docking station and replaced by another inverter module without affecting the functioning of the photovoltaic assembly or any power system that the inverter module may be a part of. The first connector, which is the female socket half of the connector assembly, may have recessed contacts with the make- first, break-last contact positioned forward. The second connector, which is the male half of the connector assembly on the inverter module, includes long pins that act as the ground connection. The long pins also act as the first engagement contact when the first and second connectors are connected to each other, and last disengagement contact when the first and the second connectors are disconnected. The long connector pins enable the inverter module to be replaced with another inverter module with a second connector while the photovoltaic assembly and power generating system is functioning, by breaking the ground contact last while disconnecting and making ground contact first while connecting. The power hot plug functionality of the connector enables an unskilled person to replace the inverter module easily without affecting the functioning of any power system that the inverter module may be a part of.

The docking station and the inverter module can also include various alignment mechanisms to enable the easy alignment of the inverter connector with the docking station's corresponding connector.

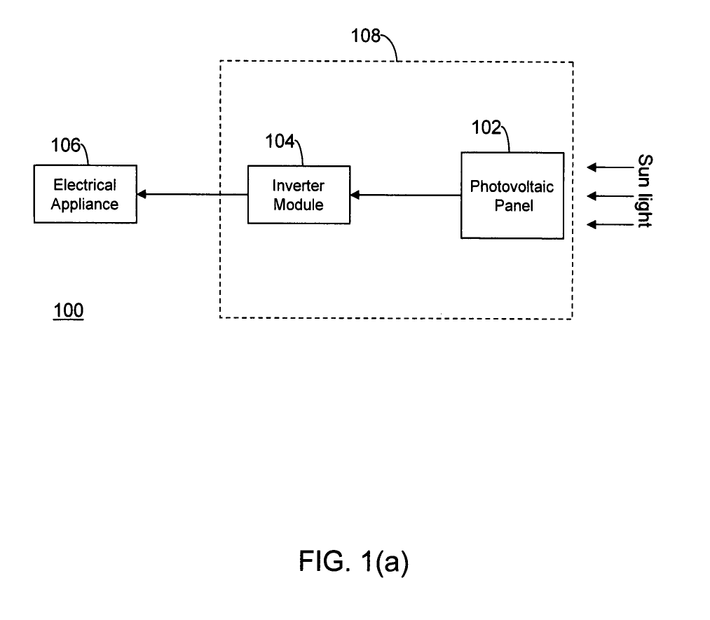

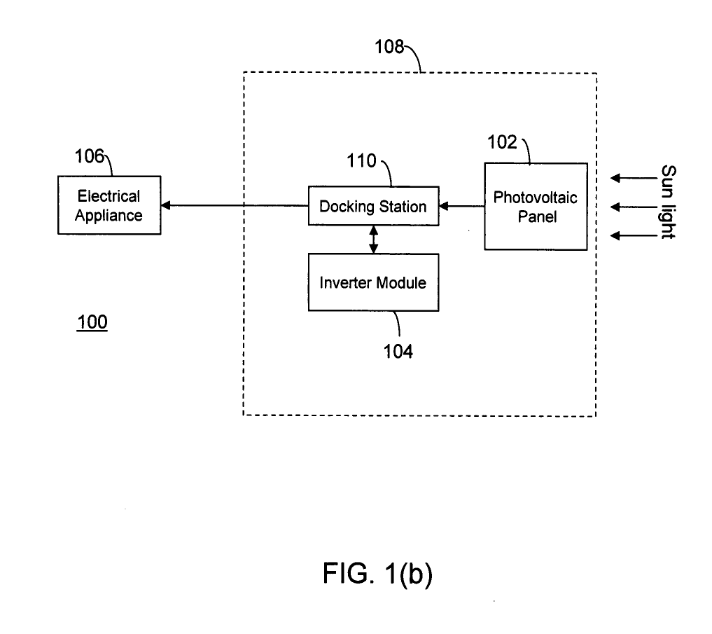

FIG. 1(a) is a block diagram of an exemplary arrangement 100, in which various embodiments of the present invention can be practiced. The exemplary arrangement 100 is shown to include a photovoltaic panel 102, an inverter module 104, and electrical appliance 106. Photovoltaic panel 102 converts the energy from sunlight into DC electricity and acts as a source of DC electricity in the photovoltaic assembly. The DC electricity is transmitted to inverter module 104, which converts it into AC electricity. The AC electricity can then be used to provide power along with AC current obtained from other paralleled photovoltaic assemblies in the power grid for operating an electrical appliance 106. Examples of electrical appliances include, but are not limited to, an electric bulb, a fan, a refrigerator, a television, and the like. Photovoltaic panel 102 and inverter module 104, which are used to convert sunlight into usable electric power, for example AC electricity, are together referred to as a photovoltaic assembly 108.

FIG. 1(b) is another block diagram of an exemplary arrangement 100, in which various embodiments of the present invention can be practiced. The exemplary arrangement 100 is shown to further include a docking station 110. The DC electricity produced by photovoltaic panel 102 is transmitted to the docking station 110. The docking station 110 in turn transmits the DC electricity to the inverter module 104. The inverter module 104 converts the DC electricity to AC electricity. The AC electricity is then transmitted by the inverter module 104 back to the docking station 110, which transmits it further to various electrical appliances.

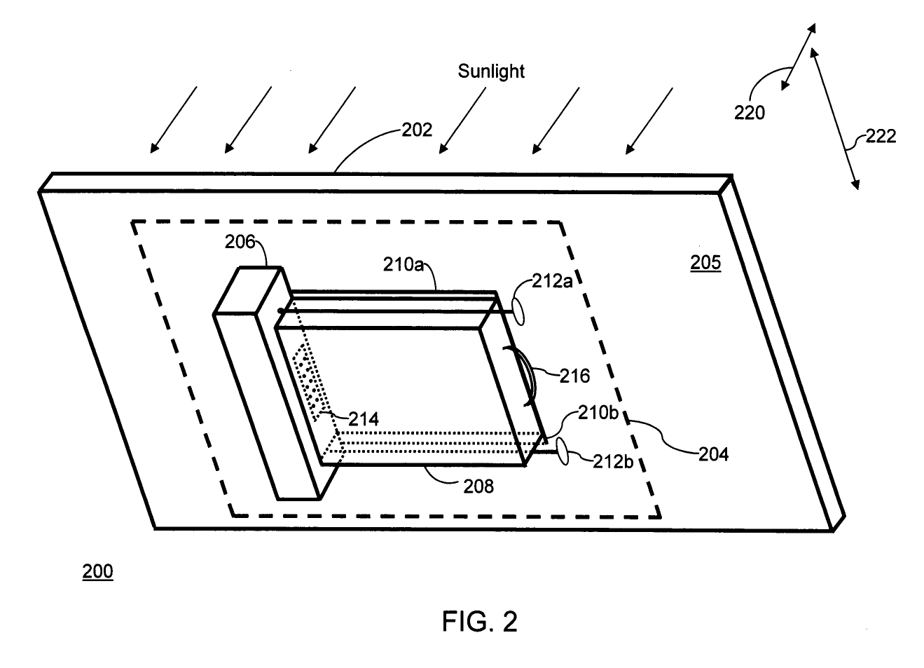

FIG. 2 illustrates a perspective view of a photovoltaic assembly 200, in accordance with an embodiment of the present invention. Those with ordinary skill in the art will appreciate that photovoltaic assembly 200 may include all or even a fewer number of components than the components shown in FIG. 2. Further, those with ordinary skill in the art will understand that photovoltaic assembly 200 may include additional components that are not shown here and are not germane to the operation of photovoltaic assembly 200, in accordance with the inventive arrangements. For the purpose of description, FIG. 2 illustrates a first direction 220 and a second direction 222.

Photovoltaic assembly 200 is shown to include a photovoltaic panel 202 and a power-conversion assembly 204. Photovoltaic panel 202 includes a first surface (not shown in FIG. 2) and a second surface 205. Photovoltaic panel 202 converts the energy received from sunlight into DC electricity. The DC electricity generated from photovoltaic panel 202 is transmitted into power-conversion assembly 204. Power-conversion assembly 204 converts the DC electricity into AC electricity. The AC electricity can be used to operate various electrical appliances. In one embodiment, the power-conversion assembly 204 can be removably mounted on second surface 205 of photovoltaic panel 202.

In another embodiment of the present invention, photovoltaic assembly 200 may contain one or more frame members for providing support to other equipments from the solar panel. In this embodiment, power-conversion assembly 204 can be removably mounted on a frame member of photovoltaic panel 202. In another embodiment, power-conversion assembly 204 can be fixed to second surface 205 of photovoltaic panel 202 or to a frame member of photovoltaic panel 202.

Although FIG. 2 illustrates the invention with inverter module 208 being mounted on surface 205 of photovoltaic panel 202, it will be readily apparent to those with ordinary skill in the art that the invention can also be practiced by mounting inverter module 208 at other locations on photovoltaic panel 202 or at locations remote from photovoltaic panel 202 when the placement of docking station 206 with respect to the inverter module is such that it does not pose a problem in establishing the connection between the inverter module 208 and the docking station 206. Inverter module 208 can be mounted at various locations, for example, a wall of a building or a house, indoor wall of building or house.

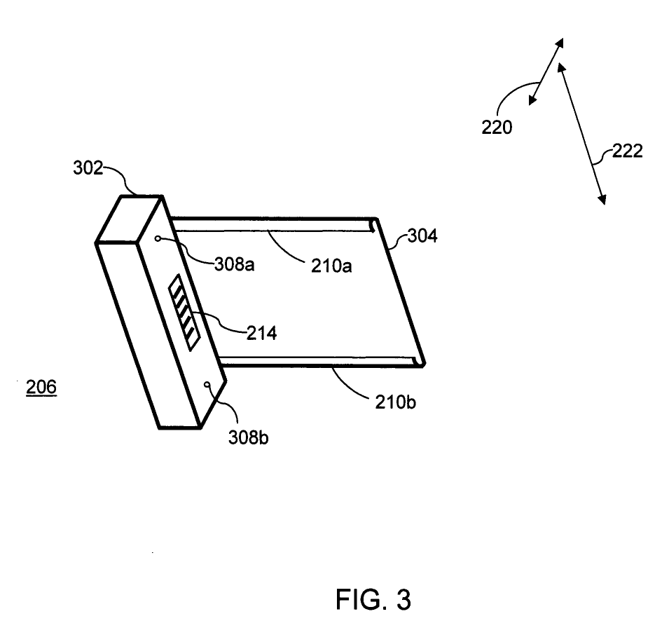

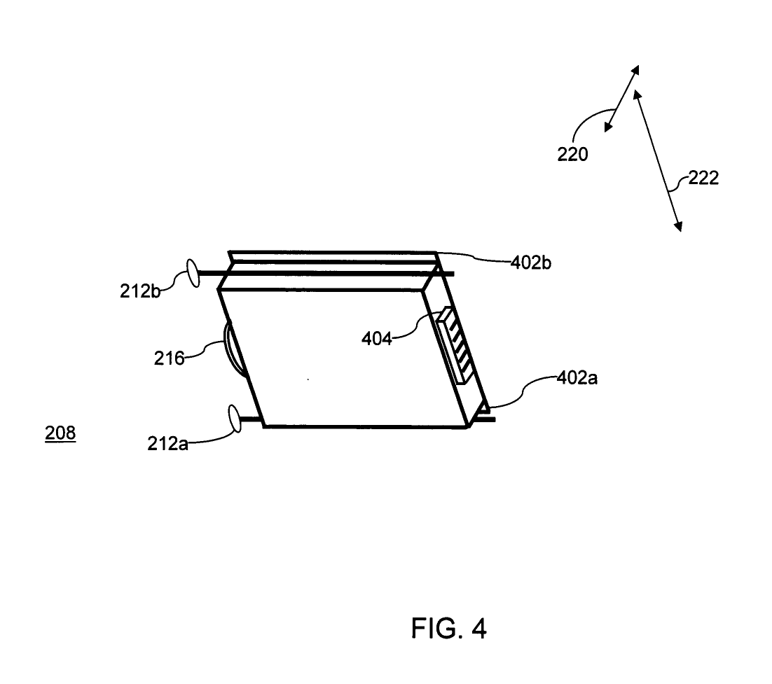

Power-conversion assembly 204 is shown to include a docking station 206 and an inverter module 208. Docking station 206, inverter module 208, and their components are explained in detail in conjunction with FIGS. 3 and 4. Docking station 206 facilitates the transmission of DC electricity from photovoltaic panel 202 to inverter module 208. In an embodiment, the DC electricity generated by photovoltaic panel 202 is transmitted to docking station 206 through wires, not shown in the figure. In this embodiment, docking station 206 can include input connections, not shown in the figure, for receiving DC electricity from photovoltaic panel 202 through the wires. These wires are connected to the input connections to transmit DC electricity from photovoltaic panel 202 to docking station 206. The wires and input connections are as readily known to a person of ordinary skill in the art.

For transmission of the DC electricity and the AC electricity between inverter module 208 and docking station 206, docking station 206 can include a first connector 214 and inverter module 208 can include a second connector 404 as shown in FIG. 4. First connector 214 and second connector 404 mate with each other, and form a connector assembly. Further, first connector 214 and second connector 404 enable inverter module 208 and docking station 206 to initiate an electric connection with each other. First connector 214 is a hot plug connector, such that inverter module 208 can be disconnected from docking station 206 and replaced by another inverter module 208 without affecting functioning of photovoltaic assembly 200 or any circuit that inverter module 208 may be a part of. First connector 214 is a female socket half of the connector assembly, and may have recessed contacts with some of the contacts being made first during a connection, and breaking last during a disconnection. Second connector 404, which is a hot pluggable connector, is the male half of the connector assembly. Second connector 404 is on inverter module 208 and includes long pins, not shown in the figure, which act as the ground connection contacts. The long pins also act as the first engagement contact when first connector 214 and second connector 404 are connected to each other and the last disengagement contact when first connector 214 and second connector 404 are disconnected. The long connector pins enable inverter module 208 to be replaced with another inverter module, similar to inverter module 208, while the photovoltaic assembly and power generating system are functioning. The power hot plug functionality of the connectors enables an unskilled person to replace inverter module 208 easily without the need to shut the entire power generating system down.

Although, for the purpose of this description, first connector 214 has been illustrated as the female socket half of the hot pluggable connector, it will be readily apparent to those with ordinary skill in the art that the invention can be implemented by having either the female or male half of the connector as first connector 214.

Docking station 206 transmits the DC electricity from photovoltaic panel 202 to inverter module 208, which converts the DC electricity to AC electricity. Docking station 206 also facilitates the transmission of AC electricity from inverter module 208 to electrical appliance 106. In an embodiment of the present invention, docking station 206 also facilitates the transmission of AC electricity from inverter module 208 to various electrical appliances via a grid tie system wherein electricity from a power grid is complemented by the AC electricity form inverter module. In an embodiment, the AC electricity generated by inverter module 208 is transmitted to electrical appliance 106 through wires, not shown in the figure. In an embodiment of the present invention, docking station 206 can include output connections. The wires are connected to the output connections for transmission of AC electricity from docking station 206 to an electrical appliance.

Inverter module 208 can be mounted to docking station 206 by using various mounting mechanisms, for example, rail guide mechanism, a slide mechanism, a pin and socket mechanism, and the like. FIG. 2 illustrates inverter module 208 mounted to docking station 206 by using a rail guide mechanism. To achieve this purpose, docking station 206 is shown to include rail guides 210a and 210b. Rail guides 210a and 210b also enable coarse adjustment of second connector 404 on inverter module 208 with first connector 214 on docking station 206. Moreover, photovoltaic assembly 200 can include mechanisms for alignment and latching of inverter module 208 with docking station 206. For the purpose of this description, photovoltaic assembly 200 is shown to include screws 212a and 212b for securing and coarsely aligning inverter module 208 with docking station 206. Fine alignment is provided by the connectors that have integral alignment pins, not shown in the figure, that engage prior to the mating of the first connector 214. This ensures that first connector 214 and second connector 404 are aligned and engaged with substantial precision. Thereafter, inverter module 208 and docking station 206 can be latched by using a latching mechanism. Various examples of latching mechanisms include, but are not limited to, a screw and a threaded hole mechanism, a clamp mechanism, a ball plunger or spring pin detent. It will be readily apparent to those skilled in the art that the invention can be practiced by using alignment and latching mechanisms; and combinations other than those mentioned above.

In an embodiment, inverter module 208 can include a handle 216 to enable holding of inverter module 208 during the insertion or removal of inverter module 208 from docking station 206.

FIG. 3 illustrates a perspective view of docking station 206, in accordance with an embodiment of the present invention. Those skilled in the art will appreciate that docking station 206 may include all or even a fewer number of components than the components shown in FIG. 3. Further, those with ordinary skill in the art will understand that docking station 206 may include additional components that are not shown here and are not germane to the operation of docking station 206, in accordance with the inventive arrangements.

Docking station 206 is shown to include a docking box 302, and a slide plate 304. Docking box 302 contains the electric components of docking station 206. Further, docking box 302 includes first connector 214, and threaded holes 308a and 308b and other electric connectors (not shown in FIG. 3). Slide plate 304 provides the mechanical support for inverter module 208 (shown in FIG. 4) and enables a coarse alignment of second connector 404 of inverter module 208 with first connector 214 of docking box 302, when inverter module 208 is slid and attached to docking box 302. Slide plate 304 includes rail guides 210a and 210b. For the purpose of description, FIG. 3 illustrates a first direction 220 and a second direction 222. Docking station 206 is shown to be oriented in such a way that a thickness of slide plate 304 is along first direction 220 and a width of slide plate 304 is along second direction 222.

Each of rail guides 210a and 210b provides a U-shaped space along first direction 220, in which rails 402a and 402b (shown in FIG. 4) of inverter module 208 can be slid. Rail guides 210a and 210b enable a coarse alignment of second connector 404 of inverter module 208 with first connector 214 of docking station in first direction 220 and second direction 222. The coarse alignment of second connector 404 of inverter module 208 with first connector 214 of docking box 302 is illustrated in conjunction with FIG. 4.

After sliding inverter module 208 towards docking box 302, second connector 404 of inverter module 208 aligns itself with first connector 214 of docking station 206 through integral alignment pins, to enable the engagement of first connector 214 and second connector 404 with substantial precision, and providing a blind mating condition. To retain inverter module 208 to docking station 206 and ensure the mating of first connector 214 and second connector 404, screws 212a and 212b present on inverter module 208 can be engaged with threaded holes 308a and 308b.

Docking station 206 can include input connections, not shown in the figure, to receive DC electricity from photovoltaic panel 202 and transmit it to inverter module 208 through the connection between first connector 214 and second connector 404. Inverter module 208 generates AC electricity that is transmitted back to docking station 206 through the connection between first connector 214 and second connector 404. Docking station 206 can also include output connections, not shown in the figure, to transmit the AC electricity to various electrical appliances. Thus, docking station 206 forms a hub to connect the incoming and outgoing wires and various electric components.

FIG. 4 illustrates a perspective view of an inverter module 208, in accordance with an embodiment of the present invention. Those skilled in the art will appreciate that inverter module 208 may include all or even a fewer number of components than the components shown in FIG. 4. Further, those with ordinary skill in the art will understand that inverter module 208 may include additional components that are not shown here and are not germane to the operation of inverter module 208, in accordance with the inventive arrangements. For the purpose of description, FIG. 4 illustrates a first direction 220 and a second direction 222.

Inverter module 208 is shown to include rails 402a and 402b, second connector 404, screws 212a and 212b, and a handle 216. Rails 402a and 402b can be slid into rail guides 210a and 210b on docking station 206 to engage inverter module 208 with docking station 206. Rails 402a and 402b together with rail guides 210a and 210b enable a coarse alignment to mount inverter module 208 on docking box 302.

Referring to FIG. 3, there is a U-shaped space between each of rail guides 210a and 210b along first direction 220. The size of this space can be larger at the end of slide plate 304 that is farthest from docking box 302. Further, at the farthest end, the size of the space is substantially greater than the dimension of rails 402a and 402b along first direction 220, for example, the thickness of rails 402a and 402b. Further, the size of the space can gradually decrease towards docking box 302. Moreover, the size of the space at the end that is closest to docking box 302 is substantially equal to the dimension of rails 402a and 402b along first direction 220, for example the thickness of rails 402a and 402b. As a result, rail guides 210a and 210b can accept rails 402a and 402b, respectively, even if inverter module 208 is substantially misaligned along first direction 220. Further, since the size of the space is substantially close to the thickness of rails 402a and 402b near docking box 302, inverter 208 gets aligned with docking box 302 while it is being slid towards docking box 206.

Similarly, at the end farthest from box 302, the dimension of slide plate 304 along second direction 222, for example, the width of slide plate 304, is substantially greater than the corresponding dimension of inverter module 208, for example the width of inverter module 208 including rails 402a and 402b. Further, at the end closest to box 302, the width of slide plate 304 can be substantially equal to the width of inverter module 208 including rails 402a and 402b. As a result, rail guides 210a and 210b can accept rails 402a and 402b, respectively, even if inverter module 208 is substantially misaligned along second direction 222.

As described above, rails 402a and 402b and rail guides 210a and 210b enable coarse alignment between inverter module 208 and docking station 206. Further, screws 212a and 212b present on inverter module 208, and threaded holes 308a and 308b provide retention when inverter module 208 is engaged with docking station 206. Further, second connector 404 on inverter module 208 can receive DC electricity and output AC electricity. Further, in an embodiment, inverter module 208 may include handle 216 to enable holding inverter module 208 during insertion or removal of inverter module 208 from docking station 206.

Although it is described that the coarse alignment is done by using rails 402a and 402b and rail guides 210a and 210b, it will be readily apparent to those skilled in the art that the invention can also be practiced by using any other means for coarse alignment.

Referring to FIGS. 3 and 4, connectors 214 and 404 are hot plug connectors, such that inverter module 208 can be disconnected from docking station 206 and replaced by another inverter module without affecting the functioning of the photovoltaic assembly 200 or any other load it may be connected to. The engagement of first connector 214 and second connector 404 provides an AC and DC electricity transmission path between inverter module 208 and docking station 206. This eliminates the need for disconnection of wire connections between inverter module 208 and docking station 206 or other electric components when there is a need to replace inverter module 208.

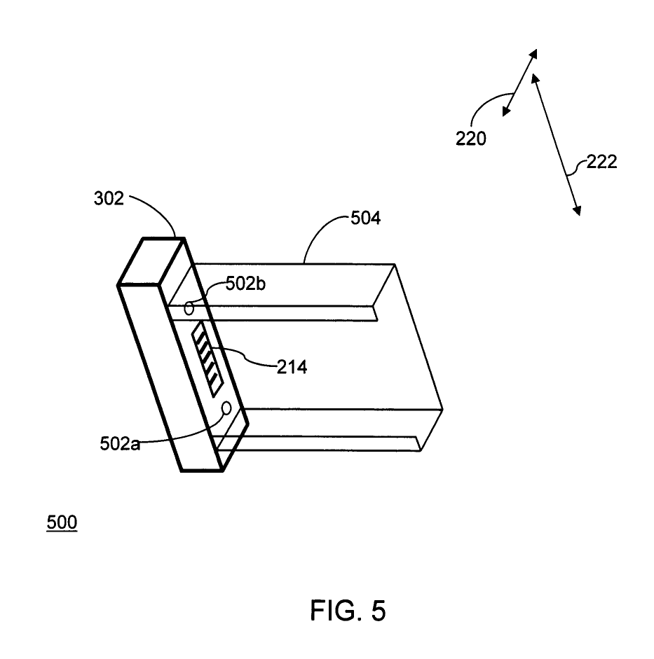

FIG. 5 illustrates a perspective view of a docking station 500, in accordance with another embodiment of the present invention. Those skilled in the art will appreciate that docking station 500 may include all or even a fewer number of components than the components shown in FIG. 5. Further, those with ordinary skill in the art will understand that docking station 500 may include additional components that are not shown here and are not germane to the operation of docking station 500, in accordance with the inventive arrangements. For the purpose of description, FIG. 5 illustrates a first direction 220 and a second direction 222.

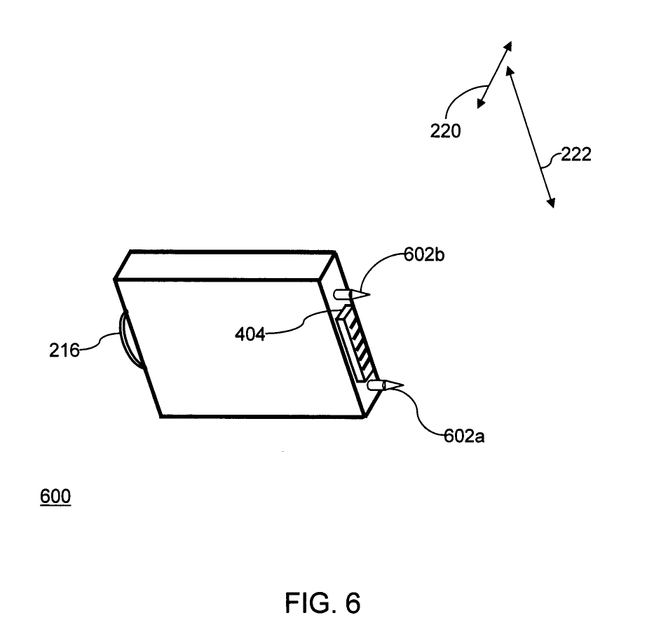

Docking station 500 is shown to include a docking box 302, and a shelf 504. Docking box 302 contains the electric components of docking station 500. In an embodiment of the present invention, docking box 302 includes first connector 214, sockets 502a and 502b, a shelf 504 and other electric connectors. Shelf 504 accepts inverter module 600 (shown in FIG. 6) and enables a coarse alignment of inverter module 600 (shown in FIG. 6) with docking box 302. Docking station 500 is shown to be oriented in such a way that the thickness of shelf 504 is along first direction 220 and the width of shelf 504 is along second direction 222. Shelf 504 enables a coarse alignment in the position of inverter module 600 (shown in FIG. 6) in first direction 220 and second direction 222. The coarse alignment of inverter module 600 (shown in FIG. 6) with docking box 302 is illustrated in conjunction with FIG. 6.

Docking box 302 and first connector 214 function as explained in conjunction with the description for FIGS. 1 to 4.

FIG. 6 illustrates a perspective view of an inverter module 600, in accordance with another embodiment of the present invention. Those skilled in the art will appreciate that inverter module 600 may include all or even a fewer number of components than the components shown in FIG. 6. Further, those with ordinary skill in the art will understand that inverter module 600 may include additional components that are not shown here and are not germane to the operation of inverter module 600, in accordance with the inventive arrangements. Inverter module 600 may include separate alignment pins 602a and 602b, and a second connector 404. For the purpose of description, FIG. 6 illustrates a first direction 220 and a second direction 222.

Referring to FIG. 5, there is vacant space inside shelf 504 along first direction 220. The size of this space can be larger at an end of shelf 504 that is farthest from docking box 302. Further, at the farthest end the size of the space is substantially greater than a dimension of inverter module 600 along first direction 220, for example, the thickness of inverter module 600. Further, the size of the space can gradually decrease towards docking box 302. Moreover, the size of the space at an end that is closest to docking box 302 is substantially equal to the dimension of inverter module 600 along first direction 220, for example the thickness of inverter module 600. As a result, shelf 504 can accept inverter module 600 even if inverter module 600 is substantially misaligned along first direction 220.

Similarly, at the farthest end from docking box 302, a dimension of shelf 504 along second direction 222, for example, the width of shelf 504, is substantially greater than the corresponding dimension of inverter module 600, for example the width of inverter module 600. Further, at the closest end, the width of shelf 504 can be substantially equal to the width of inverter module 600. As a result, shelf 504 can accept inverter module 600 even if inverter module 600 is substantially misaligned along second direction 222.

Alignment pins 602a and 602b fit in sockets 502a and 502b to enable retention of inverter module 600 to docking station 500, and insure the mating of first connector 214 and second connector 404. In an embodiment, inverter module 600 can include a latching mechanism to latch it with docking station 500. In another embodiment, the latching mechanism may be present at docking station 500.

Second connector 214 functions as explained in conjunction with the description for FIGS. 1 to 4.

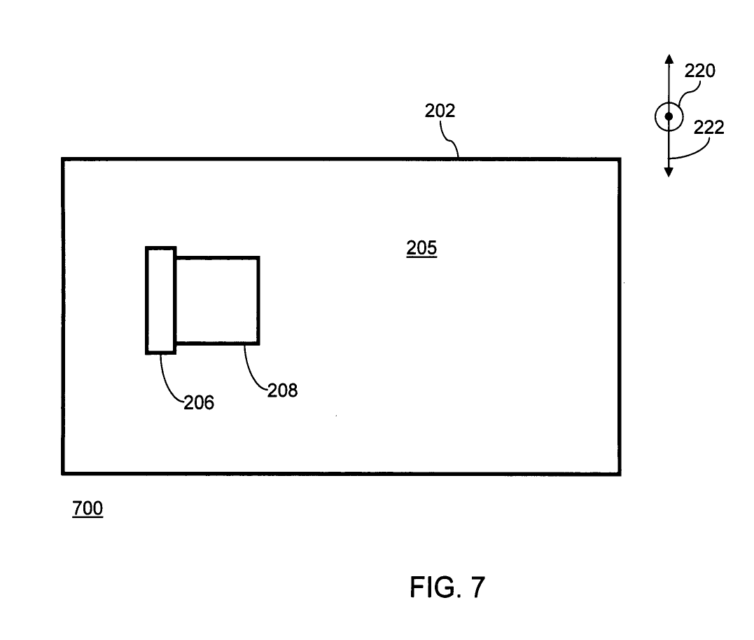

FIG. 7 illustrates a planar view of an exemplary arrangement 700 of photovoltaic assembly 200, in accordance with an embodiment of the present invention.

Exemplary arrangement 700 depicts an embodiment of the present invention where docking station 206 and inverter module 208 are installed on the rear surface of photovoltaic panel 202, i.e. second surface 205.

Further, in an embodiment, docking station 206 can be snap mounted on second surface 205. In another embodiment, docking station 206 can be screw mounted on second surface 205.

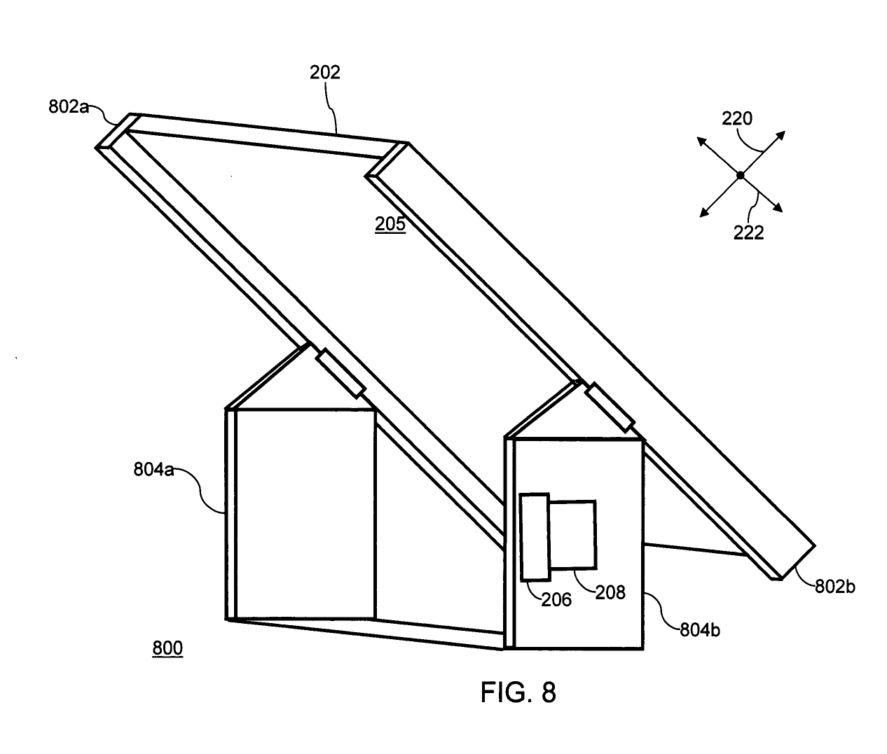

FIG. 8 illustrates a perspective view of an exemplary arrangement 800 of photovoltaic assembly 200, in accordance with another embodiment of the present invention. Exemplary arrangement 800 is shown to include photovoltaic panel 202, side frame members 802a and 802b, and base frame members 804a and 804b. Photovoltaic panel 202 is mounted on side frame members 802a and 802b. Side frame members 802a and 802b are fixedly or pivotally mounted on base frame members 804a and 804b respectively.

Those skilled in the art will appreciate that exemplary arrangement 800 may include all or even a fewer number of components than the components shown in FIG. 8. Further, those with ordinary skill in the art will understand that exemplary arrangement 800 may include additional components that are not shown here and are not germane to the operation of photovoltaic assembly 200, in accordance with the inventive arrangements.

Exemplary arrangement 800 depicts an embodiment of the present invention where docking station 206 and inverter module 208 are installed on base frame member 804a.

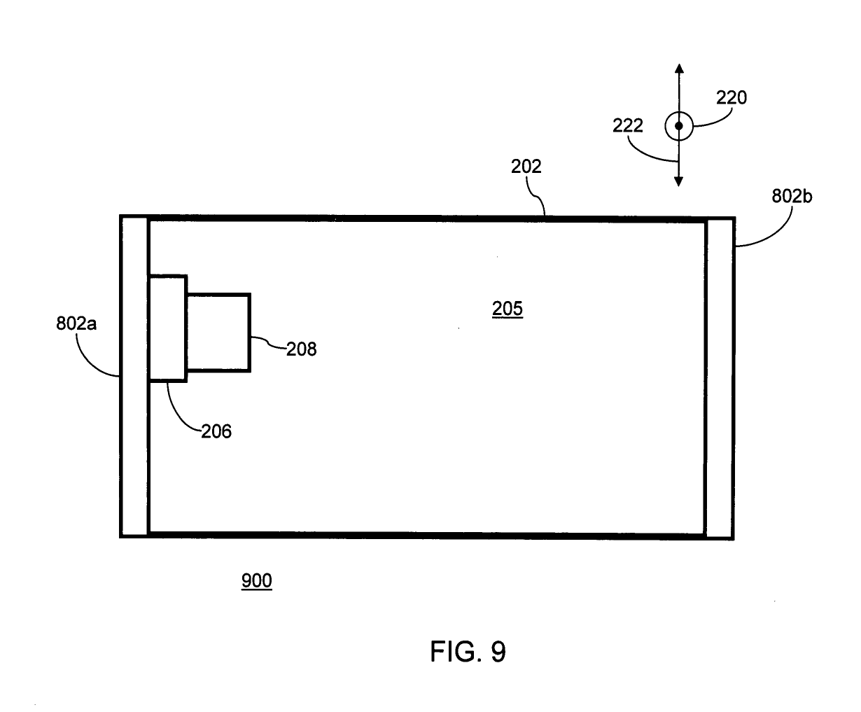

FIG. 9 illustrates a planar view of an exemplary arrangement 900 of photovoltaic assembly 200, in accordance with another embodiment of the present invention.

Exemplary arrangement 900 depicts an embodiment of the present invention where docking station 206 and inverter module 208 are installed on side frame member 802a. Further, in this embodiment docking station 206 and inverter module 208 are installed on an inner surface of side frame member 802a.

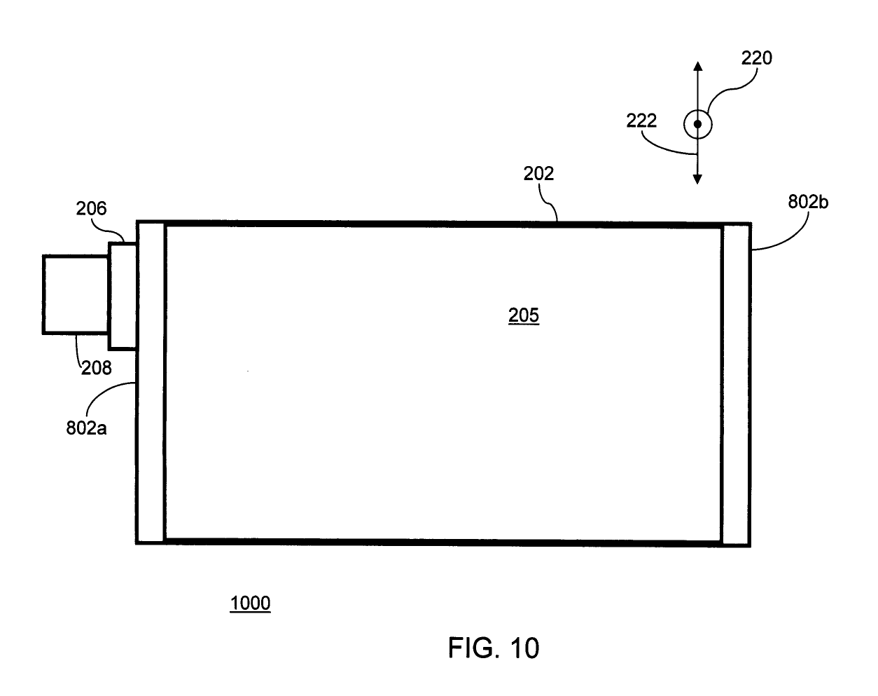

FIG. 10 illustrates a planar view of an exemplary arrangement 1000 of photovoltaic assembly 200, in accordance with another embodiment of the present invention.

Exemplary arrangement 1000 depicts an embodiment of the present invention where docking station 206 and inverter module 208 are installed on side frame member 802a. Further, in this embodiment docking station 206 and inverter module 208 are installed on an outer surface of side frame member 802a.

It will be apparent to those skilled in the art that the system can be implemented with docking station 206 mounted externally or internally to other frame parts 802a, 802b, 804a or 804b.

Although the described embodiments illustrate the present invention with a single hot plug connector, it will be readily apparent to those with ordinary skill in the art that the invention can also be practiced by having more than one hot plug connector.

It will be apparent to those skilled in the art that the system can be implemented as a combination of one or more embodiments as described above. Further, the embodiments described above are for the purpose of illustration and not to limit the scope of the invention. Various alternative embodiments of the present invention may be readily apparent to those with ordinary skill in the art.

In accordance with the present invention, the photovoltaic assembly provides various advantages. Some of the advantages are discussed below. The present invention eliminates the need to disconnect and re-establish electric connection through wires while removing and replacing the inverter module. Further, the present invention enables easy alignment of the inverter module with the docking station. The coarse and fine alignment means provided in the photovoltaic assembly of the present invention eliminate the need for a skilled person to align the inverter module with the docking station.

What is claimed is:

1. A photovoltaic assembly, the photovoltaic assembly comprising:
at least one photovoltaic panel, the at least one photovoltaic panel being capable of converting solar energy to Direct Current (DC) electricity;
an inverter module, the inverter module being capable of converting the DC electricity to Alternating Current (AC) electricity;
a docking station, the docking station being capable of transmitting the DC electricity from the at least one photovoltaic panel to the inverter module;
a first connector, the first connector capable of being mounted on the docking station, wherein the first connector is hot pluggable; and
a second connector, the second connector capable of being mounted on the inverter module, wherein the second connector is hot pluggable;
wherein the inverter module is electrically connected to the docking station by mating the first connector and the second connector.

2. The photovoltaic assembly of claim 1, wherein the docking station transmits the AC electricity from the inverter module to at least one electrical appliance.

3. The photovoltaic assembly of claim 1, wherein at least one of the first connector and the second connector comprise integral alignment pins, the integral alignment pins being capable of facilitating alignment of the first connector with the second connector.

4. The photovoltaic assembly of claim 1, further comprising a mounting mechanism for mounting the inverter module on the docking station.

5. The photovoltaic assembly of claim 1, further comprising a latching mechanism for latching the inverter module to the docking station.

6. The photovoltaic assembly of claim 1, further comprising an alignment mechanism for facilitating alignment of the inverter module and the docking station.

7. The photovoltaic assembly of claim 6, wherein the inverter module is aligned with the docking station using a set of integral alignment pins, the alignment pins being present on at least one of the first and second connector.

8. A power-conversion assembly for converting Direct Current (DC) electricity to Alternating Current (AC) electricity, the power-conversion assembly comprising:
an inverter module, the inverter module being capable of converting the DC electricity to the AC electricity;
a docking station, the docking station being capable of transmitting the DC electricity from at least one source of DC electricity to the inverter module;
a first connector, the first connector capable of being mounted on the docking station, wherein the first connector is hot pluggable; and
a second connector, the second connector capable of being mounted on the inverter module, wherein the second connector is hot pluggable;
wherein the inverter module is electrically connected to the docking station by mating the first connector and the second connector.

9. The power-conversion assembly of claim 8, wherein the docking station transmits the AC electricity from the inverter module to at least one electrical appliance.

10. The power-conversion assembly of claim 8, wherein the inverter module comprises a plurality of screws for connecting the inverter module to the docking station.

11. The power-conversion assembly of claim 10, wherein the docking station includes a plurality of threaded holes for accommodating the plurality of screws present in the inverter module.

12. The power-conversion assembly of claim 8, wherein the inverter module includes a plurality of alignment pins for connecting the inverter module with the docking station.

13. The power-conversion assembly of claim 12, wherein the docking station includes a plurality of sockets for accommodating the plurality of alignment pins of the inverter module.

14. The power-conversion assembly of claim 8, wherein the docking station includes a slide plate for supporting the inverter module.

15. The power-conversion assembly of claim 8, wherein the docking station includes a shelf for supporting the inverter module.

16. The power-conversion assembly of claim 8, wherein the inverter module comprises a handle for facilitating handling of the inverter module.

17. A docking station, the docking station being capable of performing at least one of transmitting Direct Current (DC) electricity from at least one source of DC electricity to an inverter module and transmitting Alternating Current (AC) electricity from the inverter module to at least one electrical appliance, the docking station comprising:
a first connector, the first connector being capable of electrically connecting the inverter module with the docking station, wherein the first connector is hot pluggable;
a support member, the support member being capable of supporting the inverter module; and
a docking box, the docking box being capable of providing mechanical support to the first connector and the support member, and housing electrical components of the docking station.

18. The docking station of claim 17, wherein the support member is a slide plate.

19. The docking station of claim 18, wherein the support member is a shelf.

20. A connector assembly for electrically connecting an inverter module to a docking station, the docking station being capable of transmitting Direct Current (DC) electricity from at least one source of DC electricity to the inverter module, and the inverter module being capable of converting DC electricity to Alternating Current (AC) electricity, the connector assembly comprising:
a first connector, the first connector capable of being mounted on the docking station, wherein the first connector is hot pluggable; and
a second connector, the second connector capable of being mounted on the inverter module, wherein the second connector is hot pluggable;
wherein the inverter module is electrically connected to the docking station by mating the first connector and the second connector.

21. The connector assembly of claim 20, wherein the at least one source of DC electricity is a set of photovoltaic panels, the set of photovoltaic panels being capable of converting solar energy to DC electricity.
